(19) United States
(12) Patent Application Publication
(10) Pub. No.: US 2024/0162292 A9
(43) Pub. Date: May 16, 2024

(54) N-TYPE MOSFET

(71) Applicant: Shanghai Huali Integrated Circuit Corporation, Shanghai (CN)

(72) Inventor: Wenyin Weng, Shanghai (CN)

(21) Appl. No.: 17/675,813

(22) Filed: Feb. 18, 2022

(30) Foreign Application Priority Data
Feb. 22, 2021 (CN) 202110196849.0

(51) Int. Cl. H01L 29/08; H01L 29/06; H01L 29/267; H01L 29/423; H01L 29/78

(52) U.S. Cl. CPC H01L 29/0847; H01L 29/0669; H01L 29/267; H01L 29/42392; H01L 29/785

(57) ABSTRACT

The present application discloses an N-type MOSFET, comprising: a gate structure formed on the surface of a semiconductor substrate; an embedded epitaxial layer formed on each of the two sides of the gate structure, wherein the embedded epitaxial layer fills in a groove, and the groove is formed in the semiconductor substrate; and a source region and a drain region formed in the embedded epitaxial layer on each side of the gate structure; wherein the width of the gate structure is less than 20 nm; and the embedded epitaxial layer comprises a first epitaxial layer of SiAs, or the embedded epitaxial layer is formed by stacking a second epitaxial layer of SiAs and a third epitaxial layer of SiP. The present application can improve the carrier mobility of the device and improve the short channel effect.

### CROSS-REFERENCES TO RELATED APPLICATIONS

This application claims the priority to Chinese patent application No. CN202110196849.0, filed on Feb. 22, 2021, and entitled “N-TYPE MOSFET”, the disclosure of which is incorporated herein by reference in entirety.

### TECHNICAL FIELD

The present application relates a semiconductor integrated circuit, in particular, to an N-type MOSFET.

### BACKGROUND

As the semiconductor process technology keeps on reducing target dimensions with each roadmap node, short channel effect (SCE) of a MOSFET having planar transistor structures has become increasingly significant and problematic. At the devices dimension reach under 20 nm, fin field-effect transistors (FinFETs) have been proven effective. The FinFETs have three-dimensional structures, there gate structures cover the top surfaces and side surfaces of fins, and a channel is formed on the top surface and two side surfaces of each fin, thus the ability of the gate structure to mediate between the channels is enhanced, so the SCE effect gets improved.

For smaller process dimensions such as the roadmap nodes of 5 nm or even below 3 nm, gate-all-around FETs (GAAFETs) have been proposed. In a GAAFET, a gate structure surrounds four sides of a nanometer sized wire. Among the GAAFET techniques, the multi-bridge-channel FET (MBCFET) is a type of GAAFET structures, obtained by replacing the nanometer wire in the GAAFET with a nanometer sheet.

Often, stress-enhanced structures have been used to improve the mobility of channel carriers. The stress-enhanced structures of an N-type MOSFET generally adopts an embedded SiP epitaxial layer, as shown in FIG. 1, which is a schematic diagram of an existing N-type MOSFET. A gate structure is formed on a semiconductor substrate 101, and the gate structure is shown in the dashed line box 102.

A groove 110 is formed on each side of the gate structure on the semiconductor substrate 101, and the groove 110 in FIG. 1 is Σ-shaped. The groove 110 is filled with an embedded SiP epitaxial layer 103.

N+ doped source and drain regions are formed in the SiP epitaxial layer 103.

An area between the source region and the drain region, i.e., between the grooves 110, and covered by the gate structure, is a channel region, and the channel region is P-type doped. In FIG. 1, the semiconductor substrate 101 is originally P-type doped. Therefore, the channel region is formed in the area between the source and drain grooves 110 under the gate structure in the semiconductor substrate 101. In general, fin structures of FinFETs are patterned in the semiconductor substrate 101. The cross sectional structures in FIG. 1 shows a portion that forms the fin.

FIG. 1 also shows that the gate structure, a stack of layers includes from bottom up in sequence: a gate dielectric layer 104, an N-type work function layer 105, and a metal gate 106. Sidewalls 107 are formed on the side surfaces of the gate structure. A dielectric covering layer 108 is formed on top of the metal gate 106. An interlayer film 109 covers surfaces of the gate structure and portions of the source and drain regions on both sides of the gate structure, and contact holes penetrating through the interlayer film 109 are formed on top of the source region and the drain region. FIG. 1 illustrates contact openings 111, which will be filled with metal.

The SiP epitaxial layer 103 is configured for tensile stress to apply to the channel region, so that the mobility of channel carriers, i.e., electrons, is increased during conduction, thereby improving the performance of the device. However, the phosphorus (P) in the SiP epitaxial layer 103 diffuse easily, causing instability of the SiP epitaxial layer. Therefore, to reduce the out-diffusion of phosphorus, the SiP epitaxial layer 103 is formed by stacking a SiP epitaxial sublayer 103a under a SiP epitaxial sublayer 103b, they are configured such that the doping concentration of the SiP epitaxial sublayer 103a on the periphery is lower than the doping concentration of the SiP epitaxial inner sublayer 103b, so as to reduce the out-diffusion problem of phosphorus into the channel region, thereby alleviating the short channel effect.

However, as the process node reaches as low as below 7 nm, the channel length (Lg) of the gate structure may reduce to 20 nm, wherein Lg is the distance from the source region to the drain region of the gate structure. Further reducing channel length Lg, the SCE will be seriously deteriorated regardless of how the SiP epitaxial layer 103 is configured, making the SiP epitaxial layer 103 unable to adapt to the process node below 7 nm.

### BRIEF SUMMARY

The present application provides an N-type MOSFET, which may mitigate short channel effect so the carrier mobility in transistors, thereby the performance of the transistors is improved.

The N-type MOSFET provided by the present application comprises:

a gate structure formed on the surface of a semiconductor substrate;

an embedded epitaxial layer formed on each side of the gate structure, wherein the embedded epitaxial layer fills a groove, and the groove is formed in the semiconductor substrate; and

a source region and a drain region formed in the embedded epitaxial layer on each side of the gate structure.

A process node of the N-type MOSFET is below 7 nm, and the width of the gate structure is less than 20 nm.

The embedded epitaxial layer includes a first epitaxial layer of SiAs, or the embedded epitaxial layer is formed by stacking a second epitaxial layer of SiAs and a third epitaxial layer of SiP.

In a further improvement, the N-type MOSFET is a FinFET, the FinFET comprises a fin, and the groove is formed in the fin.

In a further improvement, the N-type MOSFET is a GAAFET, the GAAFET comprises a nanometer wire, and the groove is formed in the nanometer wire.

In a further improvement, the N-type MOSFET is an MBCFET, the MBCFET comprises a nano sheet, and the groove is formed in the nano sheet.

In a further improvement, the semiconductor substrate comprises a silicon substrate.

In a further improvement, the groove is Σ-shaped.

In a further improvement, the gate structure comprises a gate dielectric layer, an N-type work function layer, and a metal gate stacked up in sequence.

In a further improvement, a sidewall is formed on a side surface of the gate structure.

In a further improvement, the material of the N-type work function layer comprises TiAl.

In a further improvement, the material of the metal gate comprises Al or W.

In a further improvement, the gate dielectric layer comprises a high dielectric constant layer.

In a further improvement, the gate dielectric layer further comprises an interface layer, and the interface layer is arranged between the high dielectric constant layer and the semiconductor substrate.

In a further improvement, a bottom barrier layer is provided between the high dielectric constant layer and the work function layer.

In a further improvement, a top barrier layer is provided between the N-type work function layer and the metal gate.

In a further improvement, the first SiAs epitaxial layer is formed by stacking a first SiAs epitaxial sublayer and a second SiAs epitaxial sublayer, and the As concentration of the first SiAs epitaxial sublayer is lower than the As concentration of the second SiAs epitaxial sublayer.

Aiming at the defect that the embedded SiP epitaxial layer seriously deteriorates the short channel effect of the device when the length of the gate structure is reduced to less than 20 nm at a process node below 7 nm, the present application provides a particular improvement to the structure of the embedded epitaxial layer, wherein the embedded epitaxial layer is set to a structure composed of a SiAs epitaxial layer or a structure formed by superposing a SiP epitaxial layer on the surface of a SiAs epitaxial layer. Since As has a smaller diffusion coefficient than that of P, the short channel effect can be significantly improved with a relatively small gate structure length. Therefore, in the present application, the carrier mobility of the device during a process of a process node below 7 nm can be improved while the short channel effect is improved, thereby improving the performance of the device.

### BRIEF DESCRIPTION OF THE DRAWINGS

The present application will be further described in detail below with reference to the drawings and specific implementations:

FIG. 1 is a schematic cross section of a structure of an existing N-type MOSFET.

FIG. 2 is a schematic cross section of a structure of an N-type MOSFET according to the first embodiment of the present disclosure.

FIG. 3 is a schematic cross section of a structure of an N-type MOSFET, according to the second embodiment of the present disclosure.

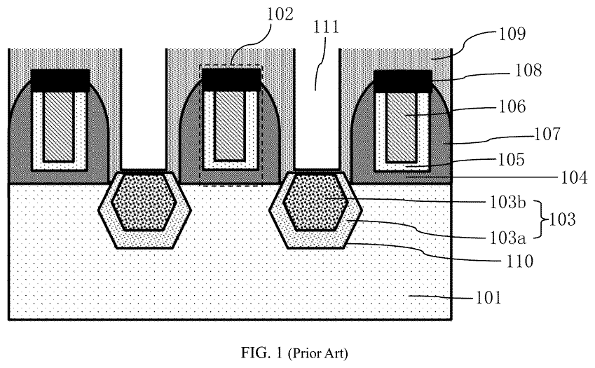

### DETAILED DESCRIPTION OF THE DISCLOSURE

### N-Type MOSFET of the First Embodiment

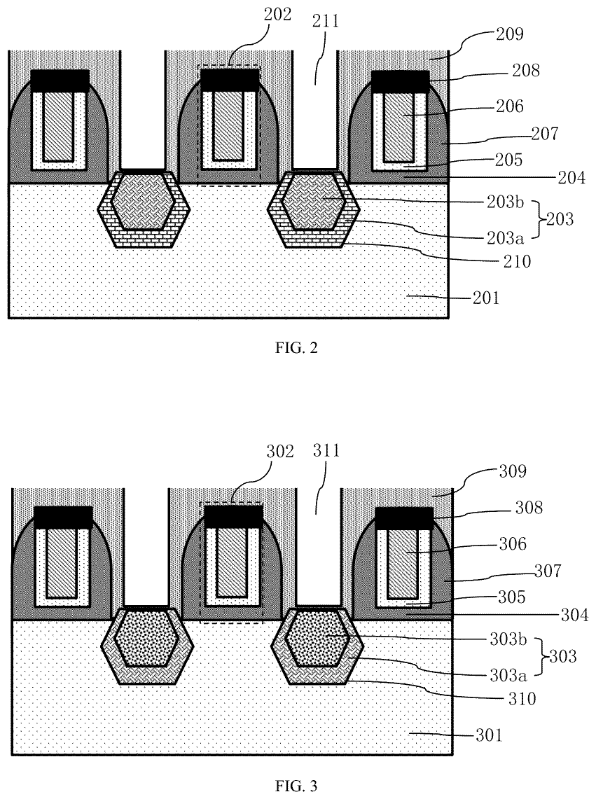

FIG. 2 shows a schematic cross section of a structure of an N-type MOSFET according to the first embodiment of the present disclosure. The N-type MOSFET includes:

a gate structure formed on the surface of a semiconductor substrate 201, here the gate structure is shown in the dashed line box 202.

An embedded epitaxial layer 203 is formed on each side of the gate structure, the embedded epitaxial layer 203 fills in a groove 210, and the groove 210 is formed in the semiconductor substrate 201.

The semiconductor substrate 201 includes a silicon substrate.

The groove 210 is Σ-shaped. The groove 210 is generally formed by dry etching for some time and wet etching for some time. Silicon's three crystal orientations (100), (010) and (111) have different etching rates during wet etching process, resulting in the Σ-shaped structure.

The Σ-shaped embedded epitaxial layer 203 are arranged to be a source region and a drain region on each side of the gate structure, and both the source region and the drain region are N+ doped.

A process node of the N-type MOSFET is below 7 nm, and the width of the gate structure is less than 20 nm.

The embedded epitaxial layer 203 is composed of a first epitaxial layer of SiAs (silicon arsenic). In some examples, the first epitaxial layer of SiAs is formed by stacking a first epitaxial sublayer of SiAs 203a and a second epitaxial sublayer of SiAs 203b, and the arsenic concentration of the first epitaxial sublayer of SiAs 203a is lower than the arsenic concentration of the second epitaxial sublayer of SiAs 203b.

In the first embodiment of the present application, the N-type MOSFET is a FinFET, the FinFET includes a fin, the groove 210 is formed in the fin, and the gate structure covers the top surface and two side surfaces of the fin. The fin is formed by patterning the semiconductor substrate 201, and the semiconductor substrate 201 of the sectional structure shown in FIG. 2 is the fin. In other embodiments, the N-type MOSFET is a GAAFET, the GAAFET includes a nanometer wire, the groove 210 is formed in the nanometer wire, and the gate structure covers all around the wire surfaces, or the top surface, the bottom surface, and two side surfaces of the nanometer wire if the wire has a rectangular cross section. Or, the N-type MOSFET is an MBCFET, the MBCFET includes a nano sheet, and the groove 210 is formed in the nano sheet.

The gate structure includes a gate dielectric layer 204, an N-type work function layer 205, and a metal gate 206 stacked up in sequence.

Sidewalls 207 are formed on the side surfaces of the gate structure, and the material of the sidewalls 207 include silicon oxide or silicon nitride.

A dielectric covering layer 208 is formed on top of the metal gate 206, and the material of the dielectric covering layer 208 includes silicon oxide or silicon nitride.

The material of the N-type work function layer 205 includes titanium alumina (TiAl).

The material of the metal gate 206 includes aluminum (Al) or tungsten (W).

The gate dielectric layer 204 includes a high dielectric-constant layer 204a.

The gate dielectric layer 204 further includes an interface layer 204b, and the interface layer 204b is arranged between the high dielectric-constant layer 204a and the semiconductor substrate 201.

The material of the high dielectric constant layer is generally HfO₂, and the material of the interface layer 204b is generally SiO₂.

A bottom barrier layer is provided between the high dielectric-constant layer and the work function layer. The bottom barrier layer is generally formed by stacking a titanium nitride (TiN) layer and a tantalum nitride (TaN) layer.

A top barrier layer is provided between the N-type work function layer 205 and the metal gate 206. The material of the top barrier layer is generally TiN or a stacked layer of TiN and Ti.

An interlayer film 209 covers the surfaces of the gate structure and of the source and the drain region on both sides of the gate structure, and contact hole penetrating through the interlayer film 209 are formed on top of the source region and the drain region. FIG. 2 illustrates contact openings 211, which will be filled with metal.

To resolve the instability issue that embedded SiP epitaxial layer seriously deteriorates with time so enhancing the short channel effect of the devices as the length of the gate structures are reduced to less than 20 nm at process nodes below 7 nm, the first embodiment of the present application discloses a particular improvement feature to the structure of the embedded epitaxial layer 203: the embedded epitaxial layer 203 comprises a structure having a SiAs epitaxial layer. Because arsenic has a smaller diffusion coefficient than that of phosphorus, the short channel effect can be significantly improved with a relatively small gate structure length. Therefore, in the first embodiment of the present application, the carrier mobility of the device made for process node below 7 nm can be improved while the short channel effect is mitigated, thereby improving the performance of the device.

### N-Type MOSFET of the Second Embodiment

FIG. 3 is a schematic cross section of a structure of an N-type MOSFET, according to the second embodiment of the present disclosure. The N-type MOSFET of the second embodiment includes:

a gate structure formed on the surface of a semiconductor substrate 301, the gate structure is shown in the dashed line box 302.

An embedded epitaxial layer 303 is formed on each side of the gate structure, the embedded epitaxial layer 303 fills in a groove 310, and the groove 310 is formed in the semiconductor substrate 301.

The semiconductor substrate 301 includes a silicon substrate.

The groove 310 is Σ-shaped. The groove 310 is generally formed by dry etching for some time and wet etching for some time. Silicon's three crystal orientations (100), (010) and (111) have different etching rates during wet etching process, resulting in the Σ-shaped structure.

A source region and a drain region are formed in the embedded epitaxial layer 303 on each side of the gate structure, and both the source region and the drain region are N+ doped.

A process node of the N-type MOSFET is below 7 nm, and the width of the gate structure is less than 30 nm.

The embedded epitaxial layer 303 is formed by stacking a second epitaxial layer of SiAs 303a and a third epitaxial layer of SiP 303b. The second epitaxial layer of SiAs 303a coats the periphery of the third epitaxial layer of SiP 303b, to eliminate phosphorus diffusion from the third epitaxial layer of SiP 303b. Impurity out-diffusion of the entire embedded epitaxial layer 303 is determined by the second epitaxial layer of SiAs 303a. Therefore, compared with an existing structure, the structure of the second embodiment of the present application can mitigate the short channel effect of the device.

In the second embodiment of the present application, the N-type MOSFET is a FinFET, the FinFET includes a fin, the groove 310 is formed in the fin, and the gate structure covers the top surface and two side surfaces of the fin. The fin is formed by patterning the semiconductor substrate 301, and the semiconductor substrate 301 of the cross sectional structure shown in FIG. 3 is the fin. In other embodiments, the N-type MOSFET is a GAAFET, the GAAFET includes a nanometer wire, the groove 310 is formed in the nanometer wire, and the gate structure covers the top surface, the bottom surface, and two side surfaces of the nanometer wire. Or, the N-type MOSFET is an MBCFET, the MBCFET includes a nanometer sheet, and the groove 310 is formed in the nano sheet.

The gate structure includes a stack of layers, including a gate dielectric layer 304, an N-type work function layer 305, and a metal gate 306 from bottom up in sequence.

Sidewalls 307 are formed on the side surfaces of the gate structure, and the material of the sidewalls 307 includes silicon oxide or silicon nitride.

A dielectric covering layer 308 is formed on the top of the metal gate 306, and the material of the dielectric covering layer 308 includes silicon oxide or silicon nitride.

The material of the N-type work function layer 305 includes TiAl.

The material of the metal gate 306 includes Al or W.

The gate dielectric layer 304 includes a high dielectric constant layer.

The gate dielectric layer 304 further includes an interface layer and the interface layer is arranged between the high dielectric-constant layer 304a and the semiconductor substrate 301.

The material of the high dielectric-constant layer includes HfO₂, and the material of the interface layer 304b includes SiO₂.

A bottom barrier layer is provided between the high dielectric-constant layer and the work function layer. The bottom barrier layer is generally formed by stacking a titanium nitride (TiN) layer and a tantalum nitride (TaN) layer.

A top barrier layer is provided between the N-type work function layer 305 and the metal gate 306. The material of the top barrier layer is generally TiN or a stacked layers of TiN and Ti.

An interlayer film 309 covers the surfaces of the gate structure and of the source and the drain region on both sides of the gate structure, and contact holes penetrating through the interlayer film 309 are formed on top of the source region and the drain region. FIG. 3 illustrates contact openings 311, which will be filled with metal.

The present application is described in detail above via specific embodiments, but these embodiments are not intended to limit the present application. Without departing from the principle of the present application, those skilled in the art can still make many variations and improvements, which should also be considered to fall into the protection scope of the present application.

What is claimed is:

1. An N-type MOSFET, comprising:
a gate structure formed on a surface of a semiconductor substrate;
an embedded epitaxial layer formed on each of the two sides of the gate structure, wherein the embedded epitaxial layer fills in a groove, wherein the groove is formed in the semiconductor substrate; and
a source region and a drain region formed in the embedded epitaxial layer on said each side of the gate structure;
wherein a width of the gate structure is less than 20 nm; and
wherein the embedded epitaxial layer comprises a first epitaxial layer of SiAs.

2. The N-type MOSFET according to claim 1, wherein the N-type MOSFET is a FinFET, the FinFET comprises a fin, and the groove is formed in the fin.

3. The N-type MOSFET according to claim 1, wherein the N-type MOSFET is a GAAFET, the GAAFET comprises a nanometer wire, and the groove is formed in the nanometer wire.

4. The N-type MOSFET according to claim 1, wherein the N-type MOSFET is an MBCFET, the MBCFET comprises a nanometer sheet, and the groove is formed in the nanometer sheet.

5. The N-type MOSFET according to claim 1, wherein the embedded epitaxial layer is formed by stacking a second epitaxial layer of SiAs and a third epitaxial layer of SiP.

6. The N-type MOSFET according to claim 1, wherein the groove is Σ-shaped.

7. The N-type MOSFET according to claim 1, wherein the gate structure comprises a gate dielectric layer, an N-type work function layer, and a metal gate stacked up in sequence.

8. The N-type MOSFET according to claim 7, wherein sidewalls are formed on side surfaces of the gate structure.

9. The N-type MOSFET according to claim 7, wherein a material of the N-type work function layer comprises TiAl.

10. The N-type MOSFET according to claim 7, wherein a material of the metal gate comprises Al or W.

11. The N-type MOSFET according to claim 7, wherein the gate dielectric layer comprises a high dielectric-constant layer.

12. The N-type MOSFET according to claim 11, wherein the gate dielectric layer further comprises an interface layer, wherein the interface layer is arranged between the high dielectric-constant layer and the semiconductor substrate.

13. The N-type MOSFET according to claim 12, wherein a bottom barrier layer is provided between the high dielectric-constant layer and the work function layer.

14. The N-type MOSFET according to claim 13, wherein a top barrier layer is provided between the N-type work function layer and the metal gate.

15. The N-type MOSFET according to claim 1, wherein the first epitaxial layer of SiAs is formed by stacking a first epitaxial sublayer of SiAs and a second epitaxial sublayer of SiAs, and the arsenic concentration of the first epitaxial sublayer of SiAs is lower than the arsenic concentration of the second epitaxial sublayer of SiAs.
